(19) United States
(12) Patent Application Publication
(10) Pub. No.: US 2024/0021655 A1
(43) Pub. Date: Jan. 18, 2024

(54) OPTOELECTRONIC DEVICE

(71) Applicant: COMMISSARIAT A L'ENERGIE ATOMIQUE ET AUX ENERGIES ALTERNATIVES, Paris (FR)

(72) Inventor: Edy AZRAK, Grenoble Cedex 9 (FR)

(73) Assignee: COMMISSARIAT A L'ENERGIE ATOMIQUE ET AUX ENERGIES ALTERNATIVES, Paris (FR)

(21) Appl. No.: 18/350,257

(22) Filed: Jul. 11, 2023

(30) Foreign Application Priority Data
Jul. 12, 2022 (FR) 22 07169

(51) Int. Cl. H01L 27/15

(52) U.S. Cl. CPC H01L 27/15

(57) ABSTRACT

An optoelectronic device includes a substrate, at least one active layer, formed on the substrate, and made of a material; defects, present in the material, and possessing an energy structure defining: a ground state in the valence band, including first and second spin states, a metastable state in the band gap, an excited state in the conduction band; a device for causing excitation of the active layer, which are configured to: make electrons transition to the excited state, then relax to the second spin state via the metastable state, so that the active layer may emit photons that make electrons transition from the second spin state to the first spin state; or make electrons transition from the second spin state to the excited state, so that the active layer may detect photons that make electrons transition from the first spin state to the second spin state by absorption.

### TECHNICAL FIELD

The invention relates to the technical field of optoelectronic devices.

The invention is notably applicable to emission and detection in the microwave frequency range. Many applications are envisageable, for example in the following fields:
communication (satellites, spacecraft, etc.);
wireless and radio networks (Internet, live radio, etc.);
household functions (microwave ovens, etc.);
radars;
medicine (treatment of the muscles, of cancers, etc.);
astronomy (space science, etc.);
physics (particle accelerators, spectroscopy, thin-film deposition).

### PRIOR ART

Sources for generating microwave emissions, such as magnetrons, klystrons, Gunn oscillators, etc., already exist.

These emission sources are not entirely satisfactory. Specifically, magnetrons and klystrons require extremely high electron-acceleration voltages (e.g. 230 000 V). A Gunn oscillator requires less power to produce microwave radiation. However, just like magnetrons and klystrons, a Gunn oscillator is large in size because of the complexity of its cavities.

### SUMMARY OF THE INVENTION

The invention aims to completely or partially remedy the aforementioned drawbacks. To this end, one subject of the invention is an optoelectronic device, comprising:
a substrate;
at least one active layer, formed on the substrate, and made of a material possessing a valence band and a conduction band that are separated by a band gap;
defects, present in the material, and possessing an energy structure defining:
a ground state in the valence band, comprising first and second spin states, the transition from the second spin state to the first spin state being intended to be radiative,
a metastable state in the band gap,
an excited state in the conduction band;
   means for causing excitation of the active layer, which are configured to:
make electrons transition to the excited state, then relax to the second spin state via the metastable state, so that the active layer may emit photons that make electrons transition from the second spin state to the first spin state; or
make electrons transition from the second spin state to the excited state, so that the active layer may detect photons that make electrons transition from the first spin state to the second spin state by absorption.

Thus, such a device according to the invention allows the problems that the sources of the prior art have with respect to compactness to be solved by virtue of monolithic integration of the active layer (thin layer, nano-filaments, etc.) with the substrate. The electrodes and all or part of the means for causing excitation of the active layer may also be monolithically integrated with the substrate in order to form an integrated circuit. Such a device is therefore compatible with the techniques of microelectronics, with silicon platforms or indeed with CMOS technology, this being impossible with the sources of the prior art.

The physical principle is also completely different to those employed in the prior art. The defects of the material of the active layer introduce at least two spin states into the ground state, which make it possible to obtain a radiative transition or detection by absorption, depending on the application envisaged for the device.

The device according to the invention may comprise one or more of the following features.

According to one feature of the invention, the means for causing excitation of the active layer comprise:
first and second electrodes, electrically connected to the active layer;
means for causing electrical excitation, arranged to apply a bias voltage across the first and second electrodes, the means for causing electrical excitation being configured to make electrons transition to the excited state, then relax to the second spin state via the metastable state, when the bias voltage is positive.

Thus, one advantage procured by the means for causing electrical excitation is to facilitate modulation of the excitation of the active layer.

According to one feature of the invention, the means for causing excitation of the active layer comprise means for causing optical excitation, configured to make electrons transition to the excited state, then relax to the second spin state via the metastable state.

According to one feature of the invention, the means for causing optical excitation are located on the same substrate as the active layer. In other words, the means for causing optical excitation are located (i.e. placed, formed) on the substrate. In other words, the active layer and the means for causing optical excitation share the same substrate. The means for causing optical excitation of the active layer are thus monolithically integrated with the substrate in order to form an integrated circuit.

According to one feature of the invention, the means for causing excitation of the active layer comprise:
first and second electrodes, electrically connected to the active layer;
means for causing electrical excitation, arranged to apply a bias voltage across the first and second electrodes, the means for causing electrical excitation being configured to make electrons transition to the excited state, then relax to the second spin state via the metastable state, when the bias voltage is positive;
means for causing optical excitation, configured to make electrons transition to the excited state, then relax to the second spin state via the metastable state.

Thus, one advantage procured is that of increasing the intensity of the radiation emitted by the device.

According to one feature of the invention, the means for causing excitation of the active layer comprise:
first and second electrodes, electrically connected to the active layer;
means for causing electrical excitation, arranged to apply a bias voltage across the first and second electrodes, the means for causing electrical excitation being configured to make electrons transition from the second spin state to the excited state when the bias voltage is negative;
means for causing optical excitation, configured to make electrons transition from the second spin state to the excited state.

Thus, one advantage procured is that of increasing the detection sensitivity of the device.

According to one feature of the invention, the means for causing optical excitation comprise at least one light-emitting diode formed on the substrate.

Thus, one advantage procured is that of facilitating integration of the means for causing optical excitation.

According to one feature of the invention, the means for causing optical excitation comprise first and second light-emitting diodes lying on either side of the active layer.

Thus, one advantage procured is that of increasing the intensity of the radiation emitted by the device.

According to one feature of the invention, the device comprises an optical resonator inside of which the active layer lies, the optical resonator being designed to interact with the means for causing optical excitation so that the means for causing optical excitation make:
electrons transition to the excited state, then relax to the second spin state via the metastable state; or
electrons transition from the second spin state to the excited state.

Thus, one advantage procured is that of increasing the confinement of the excitation radiation within the device.

According to one feature of the invention, the active layer has opposite first and second surfaces;
the device comprises:
   a first doped layer, of a first conductivity type, lying in contact with the first surface of the active layer;
   a second doped layer, of a second conductivity type opposite the first conductivity type, lying in contact with the second surface of the active layer.

Thus, one advantage procured is that of facilitating transport and manipulation of charge carriers.

According to one feature of the invention, the device comprises:
first and second electrodes, electrically connected to the active layer;
a first electrically conductive layer, preferably made of a conductive oxide, lying between the first electrode and the active layer;
a second electrically conductive layer, preferably made of a conductive oxide, lying between the active layer and the second electrode.

Thus, one advantage procured is that of facilitating injection of charge carriers.

According to one feature of the invention:
the first electrically conductive layer lies between the first electrode and the first doped layer;
the second electrically conductive layer lies between the second doped layer and the second electrode.

Thus, one advantage procured is that of facilitating both injection and transport of charge carriers.

According to one feature of the invention, the active layer comprises nano-filaments.

Thus, one advantage procured by the aspect ratio of the nano-filaments is that of improving charge-carrier confinement, of improving emission or detection capabilities, and of decreasing the power consumption of the device.

According to one feature of the invention, the device comprises:
a set of active layers;
a succession of p-i-n diodes formed on the substrate, each p-i-n diode possessing an intrinsic region formed by an active layer of the set.

Thus, one advantage procured by such a plurality of p-i-n diodes is that of increasing the intensity of the radiation emitted by the device or of increasing the detection sensitivity of the device.

According to one feature of the invention, the device comprises means for applying a magnetic field to the defects, wherein the transition between the first and second spin states is defined in presence of the magnetic field.

Thus, one advantage procured is that of being able to control the energy difference between the first and second spin states via the Zeeman effect.

According to one feature of the invention, the material of the active layer possesses a band gap wider than 1.5 eV, and preferably wider than 2 eV.

According to one feature of the invention, the material of the active layer comprises at least one component chosen from aluminium nitride AlN, gallium nitride GaN, gallium arsenide GaAs, gallium phosphide GaP, boron nitride BN, zinc oxide ZnO, zinc sulfide ZnS, magnesium telluride MgTe, magnesium selenide MgSe, silicon nitride Si₃N₄, silicon carbide SiC, silicon dioxide SiO₂, alumina Al₂O₃, germanium dioxide GeO₂, an organic crystal, and diamond C.

Thus, one advantage procured by such materials is that they possess at least one metastable state in their band gap because of the presence of defects (e.g. vacancies and/or impurities) that are also able to introduce two spins states into the ground state.

According to one feature of the invention, the defects comprise at least one element chosen from a vacancy and an impurity.

According to one feature of the invention, the substrate is made of a material chosen from silicon Si, quartz SiO₂, and sapphire Al₂O₃.

According to one feature of the invention, the frequency of the transition between the first and second spin states of the ground state is comprised between 10 MHz and 1000 GHz, or between 30 MHz and 300 GHz.

### Definitions

By “substrate”, what is meant is a self-supporting physical carrier made of a base material from which a notably electronic, mechanical or optical device for any type of application may be formed. A substrate may be a wafer, which generally takes the form of a disc obtained by cutting an ingot of a crystalline material.
By “layer”, what is meant is a layer or a plurality of sub-layers of same nature. The term “layer” may designate a thin layer that is able to be formed using a deposition technique employed in microelectronics, and the thickness of which is generally smaller than 5 μm. The term “layer” may also designate nano-filaments.
By “active layer”, what is meant is the layer designed to emit or detect electromagnetic radiation.
By “metastable state”, what is meant is an intermediate energy state (located between the conduction and valence bands) that a particle (e.g. an electron) is able to occupy temporarily. The metastable state may serve to obtain a population inversion, the electrons being able to remain at this energy level long enough. This energy level may accumulate electrons during pumping, then the electrons may collectively pass to the valence band.
By “doped layer”, what is meant is a layer containing n-type dopants or p-type dopants. By “n-type dopants”, what is meant is impurities (species) that, when introduced into a semiconductor matrix, donate an electron. By “p-type dopants”, what is meant is impurities (species) that, when introduced into a semiconductor matrix, accept an electron or donate a hole.
By “conductive oxide”, what is meant is an electrically conductive oxide, having an electrical conductivity at 300 K higher than or equal to 10² S/cm.
By “electrically connected”, what is meant is that the first and second electrodes are electrically connected to the active layer directly or indirectly. More precisely, the first and second electrodes are electrically connected directly to the active layer when the first and second electrodes make contact with the active layer. The first and second electrodes are electrically connected indirectly to the active layer when electrically conductive elements (e.g. doped layers) are interposed between the electrodes and the active layer.

### BRIEF DESCRIPTION OF THE DRAWINGS

Other features and advantages will become apparent from the detailed description of various embodiments of the invention, the description containing examples and references to the appended drawings.

FIG. 1 is a schematic cross-sectional view of a device according to the invention, used in emission mode, and illustrating a first embodiment comprising means for causing electrical excitation of the active layer.

FIG. 2 is a schematic cross-sectional view of a device according to the invention, used in emission mode, and illustrating a second embodiment comprising means for causing electrical excitation of the active layer.

FIG. 3 is a schematic cross-sectional view of a device according to the invention, used in emission mode, and illustrating a third embodiment comprising means for causing electrical excitation of the active layer.

FIG. 4 is a schematic cross-sectional view of a device according to the invention, used in emission mode, and illustrating a fourth embodiment comprising means for causing electrical excitation of the active layer.

FIG. 5 is a schematic cross-sectional view of a device according to the invention, used in emission mode, and illustrating a fifth embodiment comprising means for causing electrical excitation of the active layer.

FIG. 6 is a schematic cross-sectional view of a device according to the invention, used in emission mode, and illustrating a first embodiment comprising means for causing optical excitation of the active layer.

FIG. 7 is a schematic cross-sectional view of a device according to the invention, able to be used in emission mode or in detection mode, illustrating a first embodiment comprising means for causing electrical and optical excitation of the active layer.

FIG. 8 is a schematic cross-sectional view of a device according to the invention, used in emission mode or in detection mode, and illustrating a second embodiment comprising means for causing electrical and optical excitation of the active layer.

FIG. 9 is a partial schematic cross-sectional view of a device according to the invention, used in emission mode, and illustrating a first embodiment comprising an active layer forming a nano-filament, the active layer being intended to be electrically excited.

FIG. 10 is a partial schematic cross-sectional view of a device according to the invention, used in emission mode, and illustrating a second embodiment comprising a plurality of active layers (multilayer) forming a nano-filament, the active layers being intended to be electrically excited.

FIG. 11 is a Jablonski diagram partially showing the energy structure of a material of the active layer containing defects. “ms” designates the spin magnetic quantum number.

It should be noted that, for the sake of legibility and ease of understanding, the drawings described above are schematic, and not necessarily to scale. The cross sections are cut normal to the surface of the substrate that receives the elements of the device according to the invention.

### DETAILED DESCRIPTION OF EMBODIMENTS

For the sake of simplicity, elements that are identical or that perform the same function in the various embodiments have been designated with the same references.

One subject of the invention is an optoelectronic device, comprising:
a substrate 1,
at least one active layer 2, formed on the substrate 1, and made of a material possessing a valence band BV and a conduction band BC that are separated by a band gap Eg;
defects, present in the material, and possessing an energy structure defining:
a ground state GS in the valence band BV, comprising first and second spin states S₁, S₂, the transition T from the second spin state S₂ to the first spin state S₁ being intended to be radiative,
a metastable state MS in the band gap Eg,
an excited state in the conduction band BC;
   means for causing excitation of the active layer 2, which are configured to:
make electrons transition to the excited state, then relax to the second spin state S₂ via the metastable state MS, so that the active layer 2 may emit photons that make electrons transition from the second spin state S₂ to the first spin state S₁; or
make electrons transition from the second spin state S₂ to the excited state, so that the active layer 2 may detect photons that make electrons transition from the first spin state S₁ to the second spin state S₂ by absorption.

In other words, the means for causing excitation of the active layer 2 are configured to:
make electrons transition to the excited state, then the electrons to relax to the second spin state S₂ via the metastable state MS, so that the active layer 2 emits photons that make electrons transition from the second spin state S₂ to the first spin state S₁; or make electrons transition from the second spin state S₂ to the excited state, so that the active layer 2 detects photons that make electrons transition from the first spin state S₁ to the second spin state S₂ by absorption.

The expression “may emit photons” is understood to mean an ability (and not a potential possibility) when the means for causing excitation are actuated, i.e. when the optoelectronic device is in operation. Likewise, the expression “may detect photons” is understood to mean an ability (and not a potential possibility) when the means for causing excitation are actuated, i.e. when the optoelectronic device is in operation.

In other words, the means for causing excitation of the active layer 2 are configured to:
make electrons transition to the excited state, then relax to the second spin state S₂ via the metastable state MS, the active layer 2 being intended to emit photons that
make electrons transition from the second spin state S₂ to the first spin state S₁; or make electrons transition from the second spin state S₂ to the excited state, the active layer 2 being intended to detect photons that make electrons transition from the first spin state S₁ to the second spin state S₂ by absorption.

### Substrate

The substrate 1 is advantageously made of a material chosen from silicon Si, quartz SiO₂, and sapphire Al₂O₃.

### Active Layer

The active layer 2 has opposite first and second surfaces 20, 21.

The material of the active layer 2 advantageously possesses a band gap Eg wider than 1.5 eV, and preferably wider than 2 eV. The material of the active layer 2 advantageously comprises at least one component chosen from aluminium nitride AlN, gallium nitride GaN, gallium arsenide GaAs, gallium phosphide GaP, boron nitride BN, zinc oxide ZnO, zinc sulfide ZnS, magnesium telluride MgTe, magnesium selenide MgSe, silicon nitride Si₃N₄, silicon carbide SiC, silicon dioxide SiO₂, alumina Al₂O₃, germanium dioxide GeO₂, an organic crystal, and diamond C.

The defects advantageously comprises at least one element chosen from a vacancy and an impurity (dopant). In other words, the defects may comprise vacancies and/or impurities. By way of non-limiting example, the vacancies may be:
nitrogen-vacancy centres when the material of the active layer 2 is diamond;
silicon-vacancy centres when the material of the active layer 2 is silicon carbide.

The number of defects may be increased during formation of the defects within the material of the active layer 2 using various techniques:
(i) addition of defects (impurities) in situ;
(ii) modification of growth parameters, such as temperature, pressure, the flow of dopant precursor;
(iii) irradiation with particles (neutrons, electrons or protons) with a fluence that may reach 10²⁰ cm⁻², an energy comprised between 1 eV and 100 MeV and an exposure time comprised between 1 second and 24 hours;
(iv) implantation of ions (e.g. C, Si, N, Al, P, Ce, H) with a dose that may reach 10²⁰ cm⁻², an energy comprised between 1 eV and 100 MeV, and an exposure time comprised between 1 second and 24 hours;
(v) laser irradiation (e.g. UV, IR radiation) with a fluence comprised between 1 J·cm⁻² and 100 J·cm⁻².

A thermal anneal may be required to electrically activate dopant-type defects, i.e. to cause the dopants to migrate to substitutional sites in which they will be able to generate carriers.

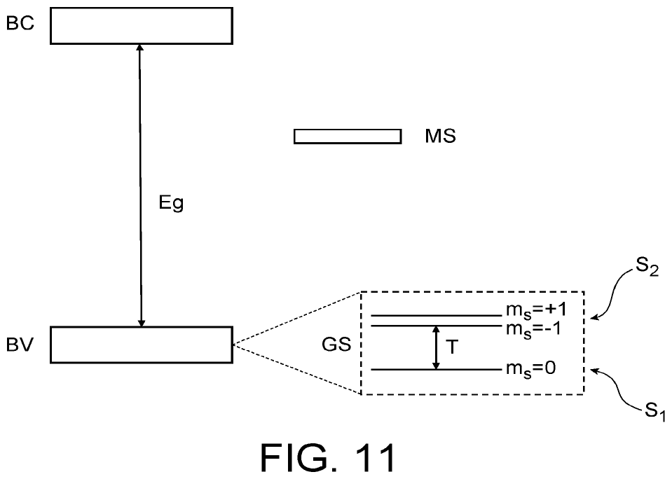

As illustrated in FIG. 11, the frequency of the transition T between the first and second spin states S₁, S₂ of the ground state GS may be comprised between 10 MHz and 1000 GHz, or between 30 MHz and 300 GHz. By way of non-limiting example, when the material of the active layer 2 is silicon carbide, the defects may be silicon-vacancy centres with a volume density of the order of 10¹⁸ cm⁻³, the transition T between the first and second spin states S₁, S₂ of the ground state GS being of the order of 127 MHz (0.53×10⁻⁶ eV).

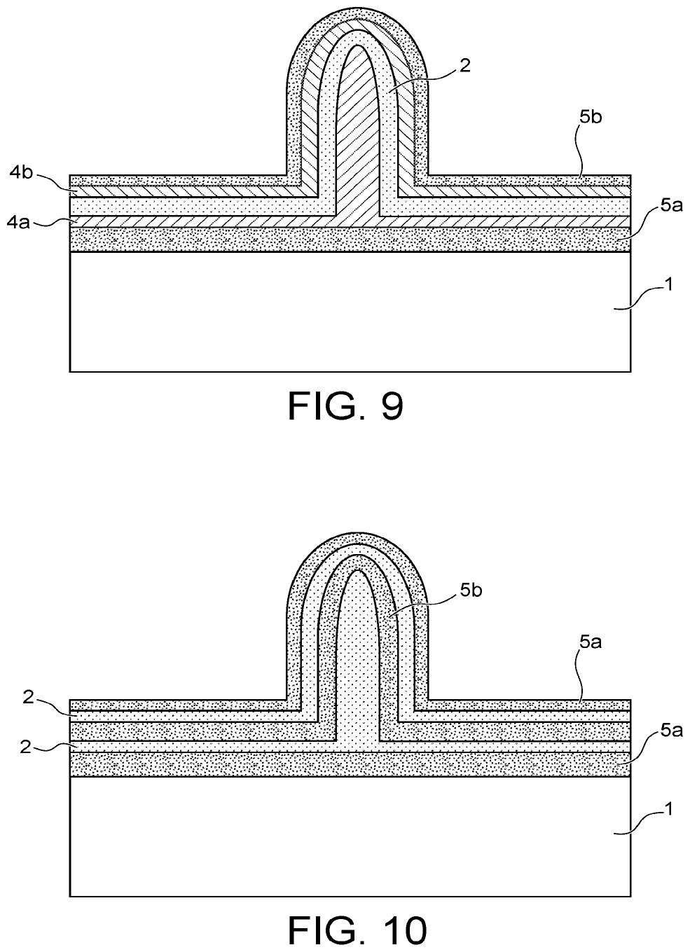

As illustrated in FIG. 9 and in FIG. 10, the active layer 2 may comprise nano-filaments. The nano-filaments are formed using techniques known to those skilled in the art, for example using a VLS method (VLS standing for vapour-liquid-solid) or an SLS method (SLS standing for solid-liquid-solid), electrodeposition, etc. By way of non-limiting example, when the material of the active layer 2 is gallium nitride, the precursor gases may be trimethylgallium (TMG), of formula Ga(CH₃)₃, and ammonia NH₃.

### Means for Causing Excitation of the Active Layer in Emission Mode

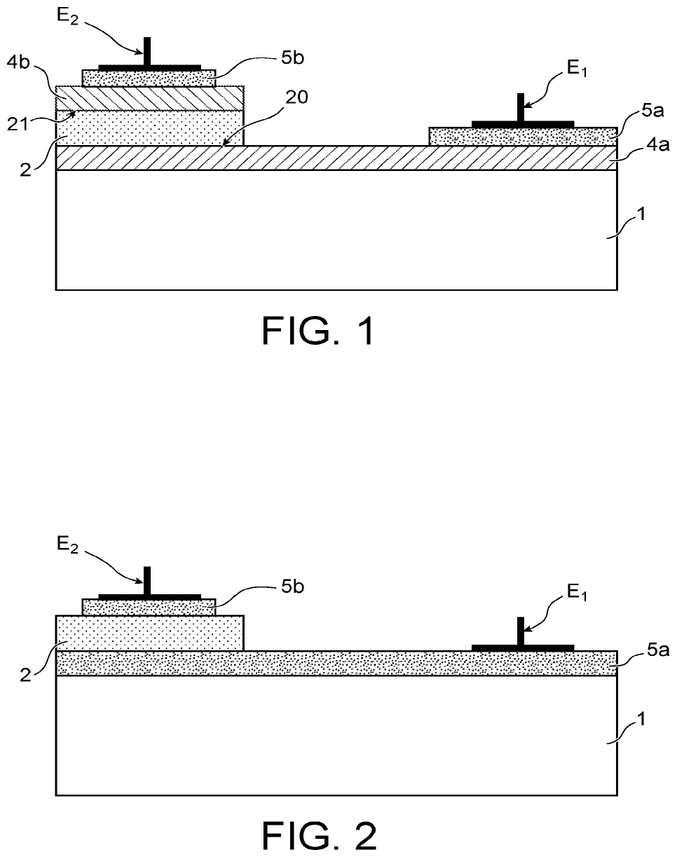

According to a first embodiment illustrated in FIGS. 1 to 5, the means for causing excitation of the active layer 2 comprise:
first and second electrodes E₁, E₂, electrically connected to the active layer 2;
means for causing electrical excitation, arranged to apply a bias voltage across the first and second electrodes E₁, E₂, the means for causing electrical excitation being configured to make electrons transition to the excited state, then relax to the second spin state S₂ via the metastable state MS, when the bias voltage is positive.

According to a second embodiment illustrated in FIGS. 6 and 8, the means for causing excitation of the active layer 2 comprise means for causing optical excitation, configured to make electrons transition to the excited state, then relax to the second spin state S₂ via the metastable state MS.

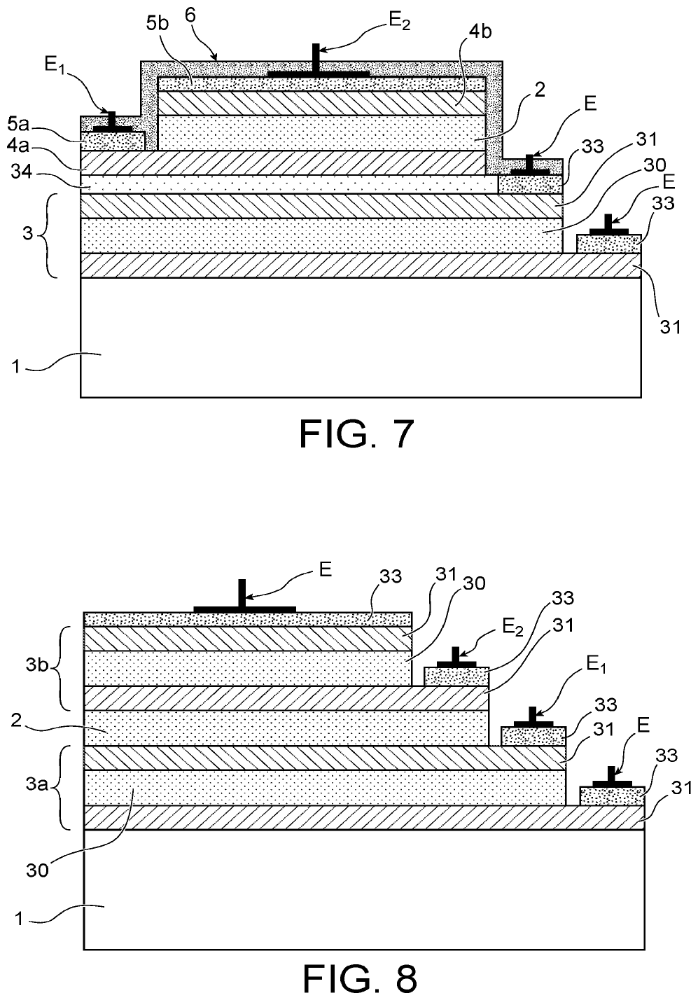

According to a third embodiment illustrated in FIG. 7, the means for causing excitation of the active layer 2 comprise:
first and second electrodes E₁, E₂, electrically connected to the active layer 2;
means for causing electrical excitation, arranged to apply a bias voltage across the first and second electrodes E₁, E₂, the means for causing electrical excitation being configured to make electrons transition to the excited state, then relax to the second spin state S₂ via the metastable state MS, when the bias voltage is positive;
means for causing optical excitation, configured to make electrons transition to the excited state, then relax to the second spin state S₂ via the metastable state MS, notably when the bias voltage is positive.

It will be noted that the transition of the electrons to the excited state achieved by the means for causing optical excitation does not require, as such, the electrodes E₁, E₂ to be electrically biased, but that this transition is achieved in combination with the means for causing electrical excitation when the bias voltage is positive.

The active layer 2 may then emit photons that make electrons transition from the second spin state S₂ to the first spin state S₁. The intensity of the emission of the photons, which is denoted I, may be written:

I∝VNρ

where:
“V” is the volume of the active layer 2,
“N” is the number of defects per unit volume,
“p” is the population inversion (i.e. the difference between the number of atoms present in the excited state and the number of atoms present in the ground state).

The device advantageously comprises a cryogenic cooling system allowing noise to be decreased and signal quality to be improved.

The transition of the electrons to the excited state, then their relaxation to the second spin state S₂ via the metastable state MS, may occur at a cryogenic temperature (of the order of a few kelvins) or at room temperature (of the order of 300 K).

The first and second electrodes E₁, E₂, and all or part of the means for causing excitation of the active layer 2 may also be monolithically integrated with the substrate 1 in order to form an integrated circuit. In particular, the means for causing optical excitation of the active layer 2 are advantageously monolithically integrated with the substrate 1 in order to form an integrated circuit. In other words, the means for causing optical excitation are placed on the same substrate 1 as the active layer 2.

### Means for Causing Excitation of the Active Layer in Detection Mode

According to one embodiment illustrated in FIG. 7, the means for causing excitation of the active layer 2 comprise:
first and second electrodes E₁, E₂, electrically connected to the active layer 2;
means for causing electrical excitation, arranged to apply a bias voltage across the first and second electrodes E₁, E₂, the means for causing electrical excitation being configured to make electrons transition from the second spin state S₂ to the excited state when the bias voltage is negative;
means for causing optical excitation, configured to make electrons transition from the second spin state S₂ to the excited state, notably when the bias voltage is negative.

It will be noted that the transition of the electrons from the second spin state S₂ to the excited state achieved by the means for causing optical excitation does not require, as such, the electrodes E₁, E₂ to be electrically biased but that this transition is achieved in combination with the means for causing electrical excitation when the bias voltage is negative.

The device advantageously comprises a cryogenic cooling system allowing noise to be decreased and signal quality to be improved.

The transition of the electrons from the second spin state S₂ to the excited state may occur at a cryogenic temperature (of the order of a few kelvins) or at room temperature (of the order of 300 K).

The first and second electrodes E₁, E₂, and all or part of the means for causing excitation of the active layer 2 may also be monolithically integrated with the substrate 1 in order to form an integrated circuit. In particular, the means for causing optical excitation of the active layer 2 are advantageously monolithically integrated with the substrate 1 in order to form an integrated circuit. In other words, the means for causing optical excitation are placed on the same substrate 1 as the active layer 2.

### Means for Causing Electrical Excitation (Electrical Pumping)

By way of non-limiting example, the means for causing electrical excitation may comprise an electrical supply circuit, formed on the substrate 1. The electrical supply circuit and the device may be monolithically integrated on the substrate 1.

### Means for Causing Optical Excitation (Optical Pumping)

As illustrated in FIGS. 6 to 8, the means for causing optical excitation advantageously comprise at least one light-emitting diode 3 formed on the substrate 1. Each light-emitting diode 3 may comprise an intrinsic region 30 and doped regions 31 lying on either side of the intrinsic region 30 so as to form a p-i-n diode. The doped regions 31 may be connected to electrodes E, E₁, E₂ via electrically conductive regions 33, which are preferably made of a conductive oxide. As illustrated in FIG. 7, the means for causing optical excitation advantageously comprise a dielectric layer 34 that is transparent (at the wavelength of the radiation emitted by the one or more light-emitting diodes 3), and that is arranged to electrically insulate the light-emitting diode 3 from the active layer 2. As illustrated in FIG. 8, the means for causing optical excitation may comprise first and second light-emitting diodes 3a, 3b lying on either side of the active layer 2. By way of non-limiting example, the means for causing optical excitation may be configured to emit radiation possessing an amount of energy of 1.397 eV when the material of the active layer 2 is silicon carbide.

The device may comprise an optical resonator inside of which the active layer 2 lies, the optical resonator being designed to interact with the means for causing optical excitation so that the means for causing optical excitation make:
electrons transition to the excited state, then relax to the second spin state S₂ via the metastable state MS; or
electrons transition from the second spin state S₂ to the excited state.

The optical resonator allows the waves emitted by the one or more light-emitting diodes 3 to be confined and the stimulated-emission effect to be perpetuated. The optical resonator may be a dielectric resonator (made of sapphire for example) or an optical cavity formed by reflective metal walls (made of copper for example). The optical resonator may be placed on the same substrate 1 as the active layer 2. In other words, the optical resonator is advantageously monolithically integrated with the substrate 1 in order to form an integrated circuit.

### Various Architectures

The device may comprise:
a first doped layer 4a, of a first conductivity type, lying in contact with the first surface 20 of the active layer 2;
a second doped layer 4b, of a second conductivity type opposite the first conductivity type, lying in contact with the second surface 21 of the active layer 2.

The device may comprise:
first and second electrodes E₁, E₂, electrically connected to the active layer;
a first electrically conductive layer 5a, preferably made of a conductive oxide, lying between the first electrode E₁ and the active layer 2;
a second electrically conductive layer 5b, preferably made of a conductive oxide, lying between the active layer 2 and the second electrode E₂.

The first electrically conductive layer 5a may lie between the first electrode E₁ and the first doped layer 4a. The second electrically conductive layer 5b may lie between the second doped layer 4b and the second electrode E₂. By way of non-limiting examples, the first and second electrically conductive layers 5a, 5b may be transparent conductive oxides, such as In₂O₃:H, InSnO, InZnO, In₂O₃:Zr, ZnO:Al, ZnSnO, ZnO:B, and ZnO:Ga. Alternatively, as illustrated in FIGS. 9 and 10, the first and second electrically conductive layers 5a, 5b may form an array of metal (Au, Ag, Cu etc.) nanowires.

As illustrated in FIG. 1, the first doped layer 4a may lie on the surface of the substrate 1, and may be formed by a wafer-scale deposit. The first electrically conductive layer 5a is formed on the first doped layer 4a. The active layer 2, the second doped layer 4b and the second electrically conductive layer 5b are successively formed on the first doped layer 4a, at distance from the first electrically conductive layer 5a.

As illustrated in FIG. 9, the first and second doped layers 4a, 4b may take the form of filaments. When the filaments of the first and second doped layers 4a, 4b are made of gallium nitride, in the case of p-type doping, the precursors may be magnesocene of formula Mg(C₅H₅)₂ or bis(methylcyclopentadienyl)magnesium of formula (CH₃C₅H₄)₂Mg. In the case of n-type doping, the precursors may be silane SiH₄ or germane GeH₄.

As illustrated in FIG. 2, the first and second doped layers 4a, 4b are optional. The first electrically conductive layer 5a may lie on the surface of the substrate 1, and may be formed by a wafer-scale deposit. The active layer 2 and the second electrically conductive layer 5b may be successively formed on the first electrically conductive layer 5a.

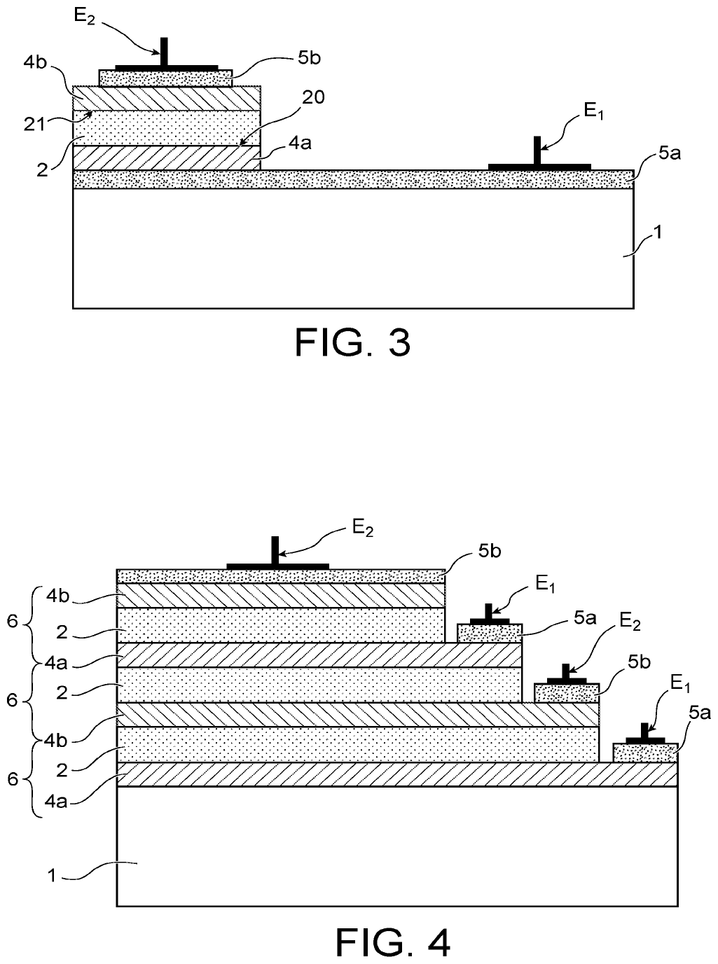

As illustrated in FIG. 3, the first electrically conductive layer 5a may lie on the surface of the substrate 1, and may be formed by a wafer-scale deposit. The first doped layer 4a, the active layer 2, the second doped layer 4b, and the second electrically conductive layer 5b may be successively formed on the first electrically conductive layer 5a.

As illustrated in FIG. 4, the device may comprise:
a set of active layers 2;
a succession of p-i-n diodes 6 formed on the substrate 2, each p-i-n diode 6 possessing an intrinsic region formed by an active layer 2 of the set.

Each active layer 2 is electrically connected to one pair of electrodes E₁, E₂.

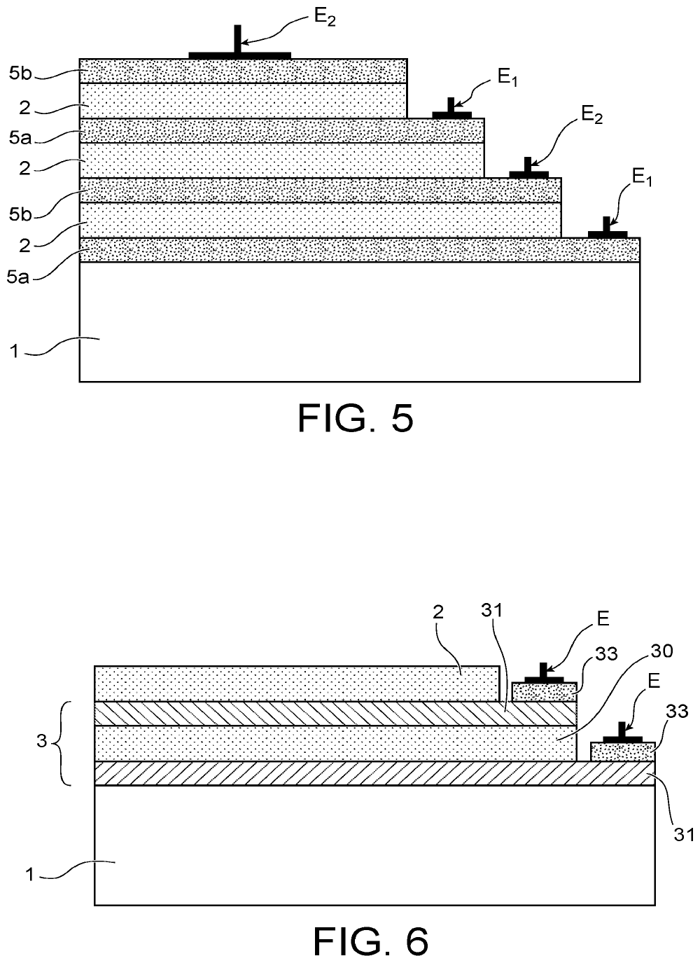

As illustrated in FIG. 5, the device may comprise a set of active layers 2, each active layer 2 making contact with first and second electrically conductive layers 5a, 5b. Each of the first and second electrically conductive layers is electrically connected to one pair of electrodes E₁, E₂.

The device may comprise means for applying a magnetic field to the defects, the transition T between the first and second spin states S₁, S₂ being defined in presence of the magnetic field. To this end, the means for applying the magnetic field may comprise a ferromagnetic layer formed on the substrate 1. The ferromagnetic layer is advantageously formed in proximity to the active layer 2.

According to one alternative, the transition T between the first and second spin states S₁, S₂ is defined in the absence of a magnetic field (ZFS, acronym of Zero Field Splitting).

As illustrated in FIG. 7, the device advantageously comprises an encapsulating layer 6, arranged to encapsulate the active layer 2. A filtering layer is advantageously formed below the encapsulating layer 6, the filtering layer being designed to filter external waves possessing a wavelength shorter than or equal to the wavelength of the one or more light-emitting diodes 3. Such a filtering layer allows optical excitation of the active layer 2 by radiation originating from the exterior medium to be prevented. The device may comprise an optical resonator comprising first and second reflective surfaces (reflective at the wavelength of the radiation emitted by the one or more light-emitting diodes 3). The first reflective surface of the optical resonator may be formed between the substrate 1 and the light-emitting diode 3. The second reflective surface of the optical resonator may be formed under the filtering layer.

The invention is not limited to the disclosed embodiments. Anyone skilled in the art will be able to consider the technically workable combinations thereof, and to substitute equivalents therefor.

1. An optoelectronic device, comprising:
a substrate,
at least one active layer, formed on the substrate, and made of a material possessing a valence band (BV) and a conduction band (BC) that are separated by a band gap (Eg);
defects, present in the material, and possessing an energy structure defining:
a ground state (GS) in the valence band (BV), comprising first and second spin states (S₁, S₂), the transition (T) from the second spin state (S₂) to the first spin state (S₁) being intended to be radiative,
a metastable state (MS) in the band gap (Eg),
an excited state in the conduction band (BC);
a device for causing excitation of the active layer, which is configured to:
make electrons transition to the excited state, then relax to the second spin state (S₂) via the metastable state (MS), so that the active layer may emit photons that make electrons transition from the second spin state (S₂) to the first spin state (S₁); or
make electrons transition from the second spin state (S₂) to the excited state, so that the active layer may detect photons that make electrons transition from the first spin state (S₁) to the second spin state (S₂) by absorption.

2. The device according to claim 1, wherein the device for causing excitation of the active layer comprises:
first and second electrodes (E₁, E₂), electrically connected to the active layer;
a device for causing electrical excitation, arranged to apply a bias voltage across the first and second electrodes (E₁, E₂), the device for causing electrical excitation being configured to make electrons transition to the excited state, then relax to the second spin state (S₂) via the metastable state (MS), when the bias voltage is positive.

3. The device according to claim 1, wherein the device for causing excitation of the active layer comprises a device for causing optical excitation, configured to make electrons transition to the excited state, then relax to the second spin state (S₂) via the metastable state (MS).

4. The device according to claim 3, wherein the device for causing optical excitation is located on the same substrate as the active layer.

5. The device according to claim 1, wherein the device for causing excitation of the active layer comprises:
first and second electrodes (E₁, E₂), electrically connected to the active layer;
a device for causing electrical excitation, arranged to apply a bias voltage across the first and second electrodes (E₁, E₂), the device for causing electrical excitation being configured to make electrons transition to the excited state, then relax to the second spin state (S₂) via the metastable state (MS), when the bias voltage is positive;
a device for causing optical excitation, configured to make electrons transition to the excited state, then relax to the second spin state (S₂) via the metastable state (MS).

6. The device according to claim 1, wherein the device for causing excitation of the active layer comprises:
first and second electrodes (E₁, E₂), electrically connected to the active layer;
a device for causing electrical excitation, arranged to apply a bias voltage across the first and second electrodes (E₁, E₂), the device for causing electrical excitation being configured to make electrons transition from the second spin state (S₂) to the excited state when the bias voltage is negative;
a device for causing optical excitation, configured to make electrons transition from the second spin state (S₂) to the excited state.

7. The device according to claim 3, wherein the device for causing optical excitation comprises at least one light-emitting diode formed on the substrate.

8. The device according to claim 7, wherein the device for causing optical excitation comprises first and second light-emitting diodes lying on either side of the active layer.

9. The device according to claim 3, comprising an optical resonator inside of which the active layer lies, the optical resonator being configured to interact with the device for causing optical excitation so that the device for causing optical excitation makes:
electrons transition to the excited state, then relax to the second spin state (S₂) via the metastable state (MS); or
electrons transition from the second spin state (S₂) to the excited state.

10. The device according to claim 1, wherein the active layer has opposite first and second surfaces;
the device comprising:
a first doped layer, of a first conductivity type, lying in contact with the first surface of the active layer;
a second doped layer, of a second conductivity type opposite the first conductivity type, lying in contact with the second surface of the active layer.

11. The device according to claim 1, comprising:
first and second electrodes (E₁, E₂), electrically connected to the active layer;
a first electrically conductive layer, made of a conductive oxide, lying between the first electrode (E₁) and the active layer;
a second electrically conductive layer, preferably made of a conductive oxide, lying between the active layer and the second electrode (E₂).

12. The device according to claim 11, wherein:
the first electrically conductive layer lies between the first electrode (E₁) and the first doped layer;
the second electrically conductive layer lies between the second doped layer and the second electrode (E₂).

13. The device according to claim 1, comprising:
a set of active layers;
a succession of p-i-n diodes formed on the substrate, each p-i-n diode possessing an intrinsic region formed by an active layer of the set.

14. The device according to claim 1, comprising a device for applying a magnetic field to the defects, wherein the transition (T) between the first and second spin states (S₁, S₂) is defined in presence of the magnetic field.

15. The device according to claim 1, wherein the material of the active layer possesses a band gap wider than 1.5 eV.

16. The device according to claim 1, wherein the material of the active layer possesses a band gap wider than 2 eV.
